(19) United States
(12) Patent Application Publication
(10) Pub. No.: US 2005/0048413 A1
(43) Pub. Date: Mar. 3, 2005

(54) Pattern forming method, semiconductor device and method for manufacturing the same

(75) Inventor: Tetsuro Nakasugi, Yokohama-shi (JP)

Correspondence Address: Finnegan, Henderson, Farabow,;Garrett & Dunner, L.L.P., 1300 I Street, N.W., Washington, DC, 20005-3315, US

(73) Assignee: KABUSHIKI KAISHA TOSHIBA

(21) Appl. No.: 10/893,947

(22) Filed: Jul. 20, 2004

(30) Foreign Application Priority Data
Aug. 28, 2003 (JP) 2003-209309

(51) Int. Cl. G03F 7/00

(52) U.S. Cl. 430/322; 430/313; 430/330

(57) ABSTRACT

There is disclosed a pattern forming method comprising providing a first film having conductivity above a substrate to be processed, providing a second film having an acid diffusion preventing function above the first film, providing a third film having photosensitivity on the second film, and exposing a predetermined pattern on the third film by applying an energy beam onto the third film.

### CROSS-REFERENCE TO RELATED APPLICATIONS

This application is based upon and claims the benefit of priority from prior Japanese Patent Application No. 2003-209309, filed Aug. 28, 2003, the entire contents of which are incorporated herein by reference.

### BACKGROUND OF THE INVENTION

1. Field of the Invention

The present invention relates to a semiconductor manufacturing process, and in particular a pattern forming method using a charged beam, a semiconductor device and a method for manufacturing the same.

2. Description of the Related Art

In general, a semiconductor manufacturing process includes various steps using a beam of charged particles (charged beam), such as exposure using an electron beam, ion injection, and plasma etching. In such steps, due to irradiation of a changed beam, an insulating film such as a resist film or an Si oxide film is easily electrically charged. When the insulating film is electrically charged, there is a strong possibility that a charged beam may be displaced from a desired position when being irradiated, or a device may be damaged. This is a serious problem. Generally, in order to prevent electrically charging the insulating film, an anti-charge film is provided above or under the resist film. Such a technique is disclosed in, e.g., Jpn. Pat. Appln. KOKAI Publications No. 7-261375, No. 2001-189261, No. 2000-191916, No. 2001-272797 and No. 2002-57151.

However, even if the anti-charge film is provided above or under the resist film, when a post-exposure bake (PEB) is carried out, acid generated from the anti-charge film due to irradiation of a charged beam reacts with the resist film, thus cross-linking and decomposing the resist film. Consequently, a larger number of defects are generated in a resist pattern, or the shape of the resist pattern worsens.

### BRIEF SUMMARY OF THE INVENTION

According to an aspect of the present invention, there is provided a pattern forming method comprising: providing a first film having conductivity above a substrate to be processed; providing a second film having an acid diffusion preventing function above the first film; providing a third film having photosensitivity on the second film; and exposing a predetermined pattern on the third film by applying an energy beam onto the third film.

According to another aspect of the present invention, there is provided a method for manufacturing a semiconductor device comprising: providing a first film having conductivity above a semiconductor substrate; providing a second film having an acid diffusion preventing function above the first film; providing a third film having photosensitivity on the second film; exposing a predetermined pattern on the third film by applying an energy beam onto the third film; and forming the pattern in the semiconductor substrate.

According to a further aspect of the present invention, there is provided a semiconductor device comprising: a semiconductor substrate where a predetermined pattern is formed, wherein: the pattern is exposed on a third film having photosensitivity, which is provided above the semiconductor substrate, by applying an energy beam onto the third film; the third film is provided on a second film which has an acid diffusion preventing function, and which is provided above the semiconductor substrate; and the second film is provided above a first film which has conductivity, and which is provided above the semiconductor. substrate.

### BRIEF DESCRIPTION OF THE SEVERAL VIEWS OF THE DRAWING

FIG. 1A is a view showing a vertical section obtained in a step in a pattern forming method according to the first embodiment of the present invention;

FIG. 1B is a view showing a vertical section obtained in another step in the pattern forming method according to the first embodiment of the present invention;

FIG. 1C is a view showing a vertical section obtained in a further step in the pattern forming method according to the first embodiment of the present invention;

FIG. 2 is a vertical sectional view showing the structure of a substrate to be processed in the pattern forming method according to the first embodiment;

FIG. 3 is a photograph which is obtained by picking up an image of a resist pattern from diagonally above, which is formed by the pattern forming method according to the first embodiment;

FIG. 4A is a view showing a vertical section obtained in a step in a pattern forming method according to the second embodiment of the present invention;

FIG. 4B is a view showing a vertical section obtained in another step in the pattern forming method according to the second embodiment of the present invention;

FIG. 4C is a view showing a vertical section obtained in a further step in the pattern forming method according to the second embodiment of the present invention.

### DETAILED DESCRIPTION OF THE INVENTION

The embodiments of the present invention will be explained with reference to the accompanying drawings.

### THE FIRST EMBODIMENT

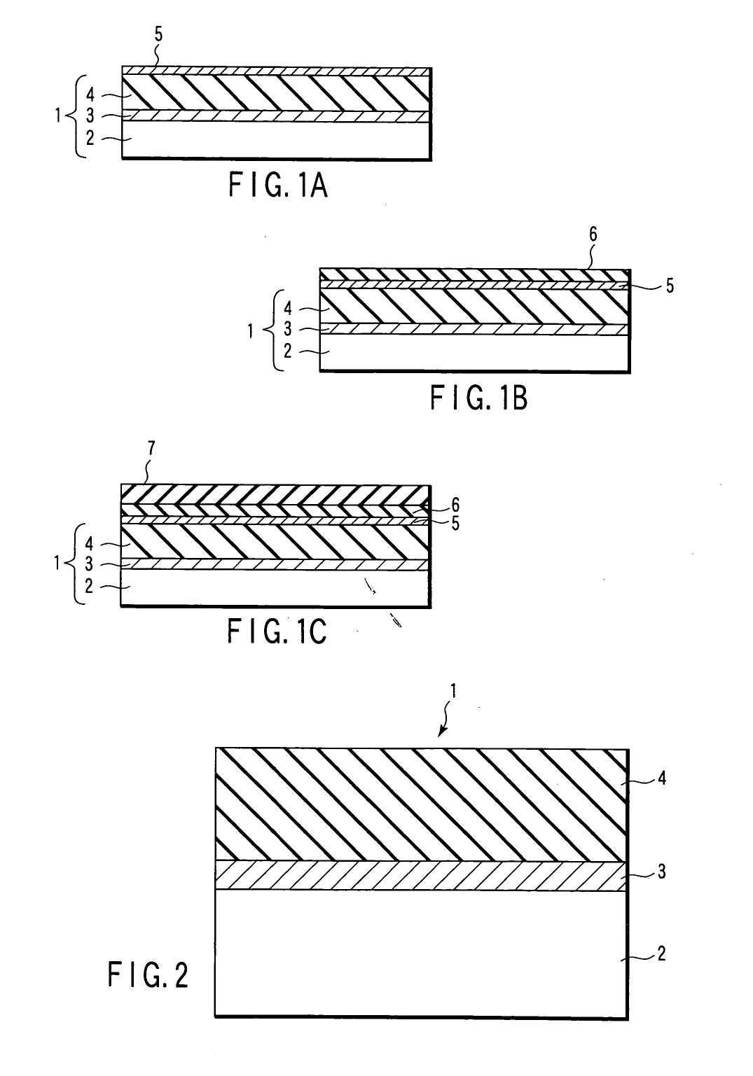

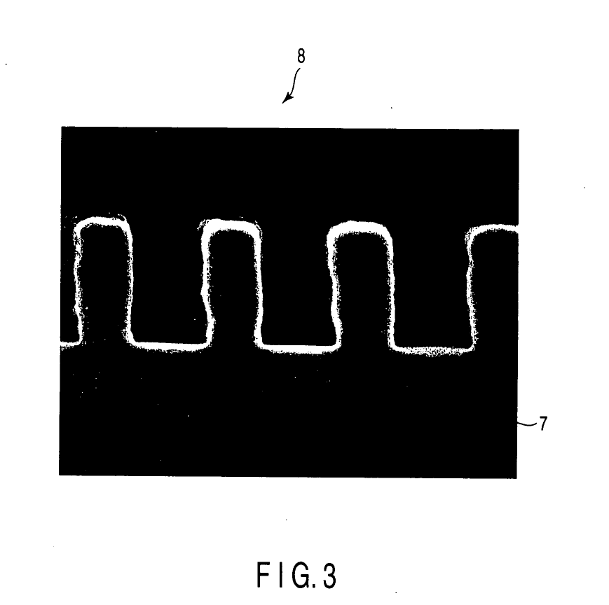

The first embodiment of the present invention will be explained with reference to FIGS. 1A to 3. FIGS. 1A to 1C respectively show vertical sections obtained in steps in the pattern forming method according to the first embodiment. FIG. 2 is a vertical sectional view of the structure of a substrate to be processed in the pattern forming method according to the first embodiment is applied. FIG. 3 is a photograph which is obtained by picking up an image of a resist pattern from diagonally above, which is formed by the pattern forming method according to the first embodiment.

The pattern forming method according to the first embodiment will be explained by referring to a case where it is applied to a wiring forming step of a series of steps for manufacturing a semiconductor device.

First, a semiconductor substrate 1 serving as a substrate to be processed, which is used in the first embodiment, will be referred to with reference to FIG. 2. As shown in FIG. 2, the semiconductor substrate 1 has a three-layer structure which comprises a silicon substrate (Si wafer) 2 serving as a main body of the substrate to be processed, a metal layer 3 serving as a conductive layer and a silicon oxide film (Si oxide film) 4 serving as an insulating layer. The metal layer 3 is provided on the Si wafer 2 to have a thickness of approximately 0.2 μm. The silicon film 4 is provided on the metal layer 3 to have a thickness of approximately 2 μm. In the silicon oxide film 4, a wiring pattern (not shown) for use in forming wiring is formed.

Next, the pattern forming method according to the first embodiment will be explained with reference to FIGS. 1A to 1C.

First, as shown in FIG. 1A, a first film 5 having conductivity is provided on the silicon oxide film 4 above the Si wafer 2. In this case, as the first film 5, a water-soluble organic film is used. The water-soluble organic film contains a component which is cross-linked and insolubilized for at least one of water and an alkali solution, when it is heated. To be more specific, as the first film 5, a wafer-soluble anti-charge film (e.g., trade name “ESPACER 100” made by Showa Denko K.K.) is used which contains a PTAS as its main component, which is cross-linked by heat. By using a rotation painting (spin coating) method, the wafer-soluble anti-charge film 5 is provided on the silicon oxide film 4 to have a thickness of approximately 10 nm. More specifically, the wafer-soluble anti-charge film 5 is rotation-painted (spin coated) onto the silicon oxide film 4 at approximately 1500 rpm for about 60 seconds. In general, a PTAS has a pH value of approximately 1.8, i.e., it is strongly acid. In the first embodiment, an addition agent (counteragent) not shown is added to the wafer-soluble anti-charge film 5 in order that it have a pH value of approximately 5.0, i.e., be weakly acid.

It should be noted that the first film 5 is not limited to a water-soluble organic film containing a PTAS as its main component. For example, a water-soluble organic film containing at least one of components expressed by chemical formulas (1)-(8) indicated below can be used as the first film 5.

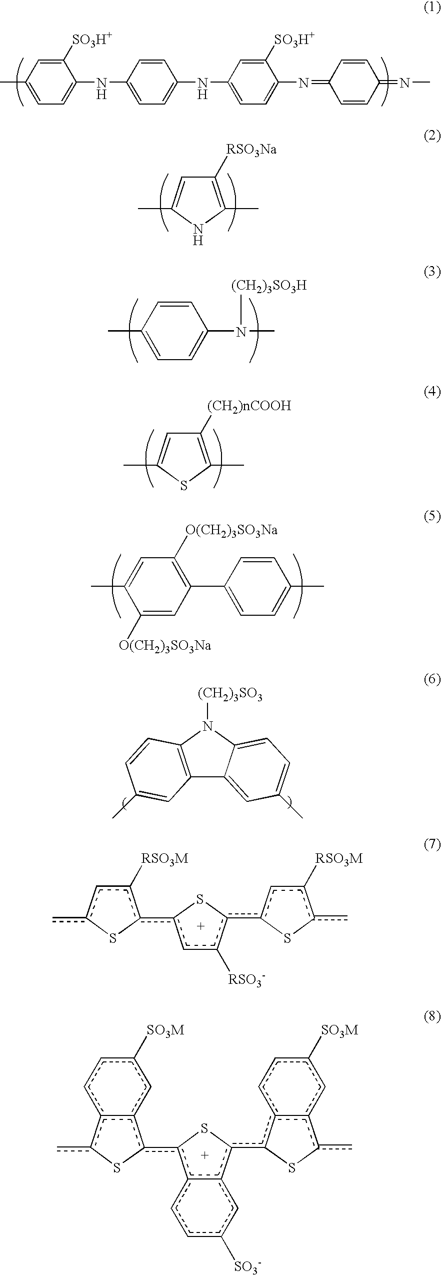

Next, the wafer-soluble anti-charge film 5 formed on the silicon oxide film 4 is heated in the air (atmosphere) at approximately 200° C. for approximately 60 seconds. Thereby, the wafer-soluble anti-charge film 5 is cross-linked and insolubilized for an alkali developing solution (not shown) for use in a developing step which will be described later. It should be noted that the temperature of heating for causing the wafer-soluble anti-charge film 5 to cross-link is not limited to approximately 200° C. It suffices that the temperature is set at approximately 100° C. or more. For example, the wafer-soluble anti-charge film 5 may be heated at approximately 120° C. for approximately 60 seconds, and then be heated at approximately 200° C. for 60 seconds. In such a manner, it may be heated in two stages.

Next, as shown in FIG. 1B, a second film 6 having an acid diffusion preventing function is provided on the wafer-soluble anti-charge film 5 subjected to the above heat treatment. In this case, as the second film 6, an organic anti-reflection film (e.g., trade name “AR5” made by Shipley Company LL.C) 6 is used which contains a thermal cross-linker which causes polymers to be cross-linked to each other due to thermal energy. To be more specific, by an applying method, the organic anti-reflection film 6 is provided on the wafer-soluble anti-charge film 5 to have a thickness of approximately 60 nm. Then, the organic anti-reflection film 6 provided on the wafer-soluble anti-charge film 5 is heated in the air at approximately 200° C. for approximately 60 seconds. As a result, the organic anti-reflection film 6 is cross-linked as containing the thermal cross-linker as stated above, and then becomes more minute. It should be noted that the second film 6 is not limited to such an organic anti-reflection film on the market as stated above. That is, any film can be used as the second film 6 as long as it has at least an acid diffusion preventing function.

Next, as shown in FIG. 1C, a third film 7 having photosensitivity is provided on the organic anti-reflection film 6 subjected to the above heat treatment. In the first embodiment, a chemical amplified type of positive resist film (photoresist film) on the market is used as the third film 7. To be more specific, the third film, e.g., the resist film 7, is provided on the organic anti-reflection film 6 by a rotation painting (spin coating) method to have a thickness of approximately 0.4 μm. Then, the resist film 7 provided on the organic anti-reflection film 6 is heated at approximately 90° C. for 90 seconds.

Thereafter, an energy beam is applied onto the resist film 7 subjected to the above heat treatment to write (expose) a predetermined pattern in the resist film 7 (this is not illustrated in any of the drawings). In this case, the pattern is written by using an electron beam machine (not shown) using an electron beam as an energy beam. To be more specific, a variable formation type electron beam machine (e.g., trade name “HL800D” made by Hitachi, Ltd.) for applying an electron beam at an acceleration voltage of approximately 50 keV is used as the electron beam machine. However, the electron beam machine is not limited to the variable formation type electron beam machine. For example, a charged-beam exposure machine such as a beam machine using an ion beam may be used as long as its function is equivalent to the function of the above electron beam machine. Also, it should be noted that the resist film 7 is set to have sensitivity of approximately 10 μC/cm² for an electron beam applied to at an acceleration voltage of approximately 50 keV.

Next, the resist film 7 where the pattern is written by exposure is subjected to a post-exposure bake (PEB) processing (which is not illustrated in any of the drawings). The PEB processing is carried out by using a heating unit not shown, which is provided along with the electron beam machine. In general, such a pattern writing exposure using an electron beam as stated above is carried out in a vacuum. However, if the resist film 7 were exposed to the atmosphere for a long time, where the pattern is written by exposure, acid generated in the resist film 7 by pattern writing exposure would be inactivated by alkali in the atmosphere. Consequently, the shape of the resist pattern would worsen, or the sensitivity of the resist film 7 would lower. In such circumstances, in the first embodiment, after being moved out of the electron beam machine, the resist film 7 where the pattern is written by exposure is quickly subjected to the PEB processing by using the heating unit provided along with the electron beam machine, as a result of which the shape of the resist pattern barely worsens, and the sensitivity of the resist film 7 barely lowers.

Then, the resist film 7 subjected to the PEB processing, etc. are developed by using an alkali developing solution for approximately 60 seconds (this is not illustrated in any of the drawings). In this case, as the alkali developing solution, a TMAH (tetramethylammoniumhydroxyoxide) solution is used in which the concentration of TMAH is approximately 2.38%. Due to the above development, a resist pattern not shown is formed in the resist film 7.

Then, by using the resist pattern in the resist film 7 as a mask, the organic anti-reflection film 6 and the water-soluble anti-charge film 5 are subjected to an etching processing (which is not illustrated in any of the drawings).

Furthermore, by using the resist pattern and the organic anti-reflection film 6 and water-soluble anti-charge film 5 subjected to etching processing as a mask, the silicon oxide film 4, which serves as a base layer, is subjected to an etching processing (this is not illustrated in any of the drawings). Thereby, a predetermined wiring pattern not shown is formed in the silicon oxide film 4. That is, when all the above steps end, the complete processing of the pattern forming method according to the first embodiment ends. The pattern forming method according to the first embodiment will be referred to as, e.g., a single-layer process (normal process).

The pattern forming method according to the first embodiment has the following features:

Firstly, in the first embodiment, the water-soluble anti-charge film 5 including the PTAS as its main component is heated at approximately 100° C. or more, after being formed by the rotation painting (spin coating) method. Thereby, components in the anti-charge film 5 are cross-linked. Then, the anti-charge film 5 is insolubilized for an alkali developing solution. Thus, the anti-charge film 5 can be formed under the resist film 7.

Secondly, the following feature is obtained:

When the anti-charge film 5 is heated at approximately 90° C. or less, at which cross-linking does not easily occur, its resistance value becomes approximately 1 e6Ω. On the other hand, when the anti-charge film 5 is heated at 100° C. or more, and is cross-linked, as in the first embodiment, its conductivity is approximately 1 E8Ω. That is, when the anti-charge film 5 itself is cross-linked, its conductivity lowers. However, from the result of an experiment made by the inventors of the present invention, it has been found that even when the conductivity of the anti-charge film 5 is approximately 1 E8Ω, the anti-charge film 5 has a sufficient anti-charge effect in a pattern writing exposure using an electron beam.

Thirdly, the following feature is obtained:

The anti-charge film 5 used in the first embodiment itself, as stated above, is strongly acid. Also, in the chemical amplified type of resist film 7 used in the first embodiment, cross-linking and decomposition are caused by acid which is generated in the film when the pattern writing exposure is carried out. Therefore, if the anti-charge film 5 contains strong acid, when the acid reaches the resist film 7, the shape of the resist pattern may worsen, or the sensitivity of the resist film may change. Furthermore, after the developing processing, part of the resist film 7 which should remain may be peeled off, or part of the resist film 7 which should be removed may remain. In view of such circumstances, in the first embodiment, an addition agent is added to the anti-charge film 5 so as to adjust the pH value of the anti-charge film 5 to approximately 5, thereby, preventing acid in the anti-charge film 5 from influencing the resist film 7.

Fourthly, in the first embodiment, after formation of the anti-charge film 5, the organic anti-reflection film 6 is formed on the anti-charge film 5. As stated above, the organic anti-reflection film 6 becomes more minute when being heated at approximately 200° C. It thus prevents acid in the anti-charge film 5 from being diffused, and reaching the resist film 7.

Fifthly, in the first embodiment, the thickness of the anti-charge film 5 is set at approximately 10 nm or less. As a result, an error in dimension which would be made when etching the water-soluble anti-charge film 5 and the silicon oxide film 4 serving as the base film can be reduced.

Moreover, the pattern formation method according to the first embodiment having the above features has the following advantages:

FIG. 3 is a photograph of a resist pattern 8 formed by the pattern formation method according to the first embodiment. In the first embodiment, the anti-reflection film 6, which prevents diffusion of acid, is formed between the anti-charge film 5 and the resist film 7. Thereby, even if the anti-charge film 5 containing a PTAS as its main component is formed under the resist film 7, worsening of the shape of the resist pattern 8 can be restricted. That is, by the pattern formation method according to the first embodiment, a satisfactory resist pattern 8, which barely worsens in shape, and barely has defects, is formed as shown in FIG. 3.

Also, even if an insulating film (silicon oxide film) 4 having a great thickness is formed above the Si wafer 2, since the anti-charge film 5 is formed under the resist film 7, it can prevent displacement of an electron beam which would occur due to charging of the insulating film 4.

Furthermore, in the case where an anti-charge film is formed above a resist film, it is necessary to peel off the anti-charge film formed above the resist film by using a weak alkali developing solution, after writing a pattern in the resist film. On the other hand, in the pattern forming method according to the first embodiment, the PEB processing can be performed on the resist film 7 without peeling off the anti-charge film 5, since the anti-charge film 5 is formed under the resist film 7. As a result, the number of steps for manufacturing the resist pattern can be reduced, thus improving the productivity of semiconductor devices (not shown) having semiconductor substrates 1, as compared with the conventional pattern forming method.

In the conventional pattern forming method, a PRB unit and a water/alkali solution unit for peeling off the anti-charge film are needed as resist processing units to be provided along with the electron beam machine. On the other hand, the pattern forming method according to the first embodiment does not need a unit or units for peeling off the anti-charge film, and necessary equipments can be thus reduced.

In addition, in the pattern forming method according to the first embodiment, the anti-charge film 5 is formed thin as stated above. Thus, the variance in dimension among anti-charge films 5 subjected to the etching processing can be reduced.

As explained above, according to the first embodiment, charging is restricted when a pattern is written by using a charged beam (energy beam), and patterns can be easily formed with a high precision and a high productivity, as compared with the conventional forming method.

### THE SECOND EMBODIMENT

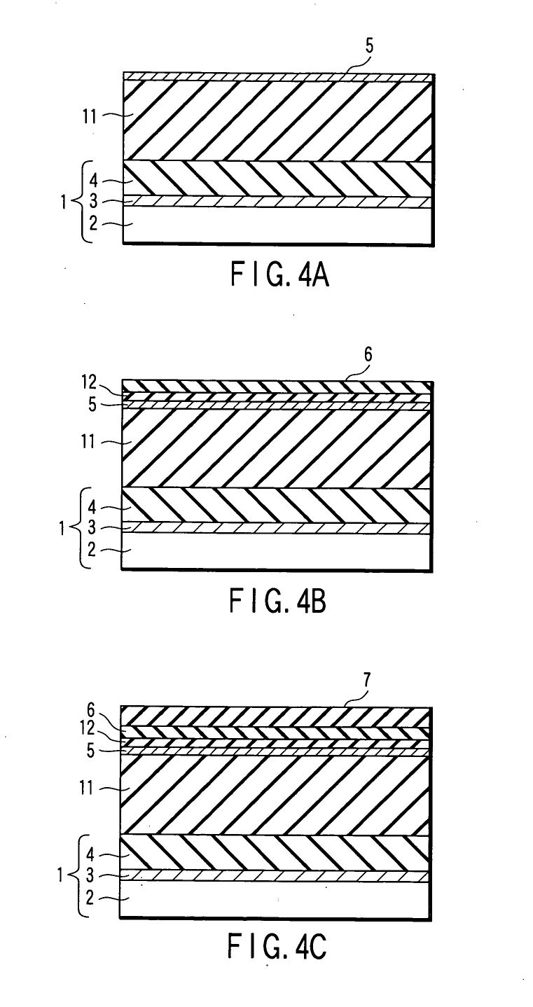

The second embodiment according to the present invention will be explained with reference to FIGS. 4A to 4C, which respectively show vertical sections obtained in steps in the pattern forming method according to the second embodiment. With respect to the second embodiment, the same elements as in the first embodiment are respectively denoted by the same reference numerals as in the first embodiment, and their detail explanations will be omitted.

The above explanation of the first embodiment is given by referring to the case where a pattern is written by using an electron beam applied at an acceleration voltage of approximately 50 keV. On the other hand, the second embodiment will be explained by referring to the case where a pattern is drawn by using an electron beam applied at an acceleration voltage of approximately 5 keV.

In the second embodiment, although the same semiconductor substrate 1 as in the first embodiment is used as the substrate to be processed, an electron beam is applied at a lower voltage than that in the first embodiment, and thus a so-called pattern transferring technique is further added to the pattern forming method according to the first embodiment. Then, the pattern forming method according to the second embodiment using the pattern transferring technique will be explained with reference to FIGS. 4A to 4C.

First, as shown in FIG. 4A, a fourth film 11 serving as a lower layer film is provided on a silicon oxide film 4 above a Si wafer 2, the fourth film 11 being required in order that a pattern exposed in a resist film 7 be transferred on the silicon oxide film 4 of the semiconductor substrate 1. In this case, as the fourth film 11, an organic film is used, which contains carbon as its main component, and is non-photosensitive. The organic film can be obtained by rotation painting (spin coating), e.g., a novolac resin, etc. onto the silicon oxide film 4, and baking them at approximately 300° C. It will be hereinafter referred to as an organic lower film 11.

Next, as shown in FIG. 4A, a water-soluble anti-charge film 5 is formed on the organic lower film 11 (i.e., it is located above the silicon oxide film 4) as in the first embodiment. In this case, the water-soluble anti-charge film 5 is formed to have a thickness of approximately 5 nm.

The water-soluble anti-charge film 5 provided above the silicon oxide film 4 is heated in the air at approximately 200° C. for 60 seconds. This is the same as in the first embodiment.

Then, as shown in FIG. 4B, a fifth film 12 is provided on the water-soluble anti-charge film 5 subjected to the above heat treatment. In this case, the fifth film 12 is provided to have a thickness of approximately 60 nm by rotation painting (spin coating) an SOG (Spin On Glass) onto the water-soluble anti-charge film 5. The fifth film 12 (which will be hereinafter referred to as an SOG 12) provided on the water-soluble anti-charge film 5 is heated at approximately 250° C. for 120 seconds.

On the SOG 12 subjected to the above heat treatment, an organic anti-reflection film 6 is formed. This is also the same as in the first embodiment.

On the organic anti-reflection film 6, a resist film 7 is formed as shown in FIG. 4C as in the first embodiment. However, in the second embodiment, the thickness of the resist film 7 is set at approximately 0.2 μm.

Next, an electron beam is applied onto the resist film 7 to write a predetermined pattern as in the first embodiment. However, in the second embodiment, the acceleration voltage of the electron beam is set at approximately 5 keV, and the sensitivity of the resist film 7 is set at approximately 0.5 μC/cm² with respect to the electron beam applied at an acceleration voltage of approximately 5 keV.

On the resist film 7 where the pattern is written, etc., a PEB processing is performed as in the first embodiment.

The resist film 7, etc., subjected to the PEB processing, are developed by using an alkali developing solution for approximately 60 seconds as in the first embodiment. Thereby, a resist pattern not shown is formed in the resist film 7.

Thereafter, the organic anti-reflection film 6, the SOG 12 and the water-soluble anti-charge film 5 are etched by using the resist pattern in the resist film 7 as a mask as in the first embodiment.

Then, the organic lower film 11 is etched by using the resist pattern and the etched organic anti-reflection film 6, SOG 12 and water-soluble anti-charge film 5 as a mask.

Lastly, the silicon oxide film 4 is etched by using the etched organic lower film 11 as a mask. Thereby, a predetermined wiring pattern not shown is formed in the silicon oxide film 4. That is, the complete processing of the pattern forming method ends when the above steps end. It should be noted that the pattern forming method according to the first embodiment is referred to as the single-layer process, whereas that according to the second embodiment will be referred to as a multi-layer process.

As explained above, according to the second embodiment, the same advantages can be obtained as in the first embodiment. Furthermore, in the. second embodiment, the pattern writing exposure barely damages a region located in the vicinity of a region to be subjected to the pattern writing exposure. This is because the acceleration voltage (exposure energy) at which an electron beam is applied in the pattern writing exposure in the second embodiment is approximately 1/10 of that in the first embodiment. Therefore, according to the second embodiment, patterns can be easily formed at a high productivity and with a high precision.

### THE THIRD EMBODIMENT

The third embodiment of the present invention will be explained. A semiconductor device and a method for manufacturing the same, according to the third embodiment, will be briefly explained, and their illustrations will be omitted.

The manufacturing method of the semiconductor device according to the third embodiment includes steps of forming a pattern in the semiconductor substrate 1 by using the above-mentioned pattern forming method according to the first embodiment or the second embodiment. As mentioned above, by the pattern forming method according to the first embodiment or the second embodiment, patterns can be easily formed in semiconductor substrates 1 at a high productivity and with a high precision. Therefore, by the manufacturing method according to the third embodiment, minute semiconductor elements to be incorporated into semiconductor devices not shown can be easily manufactured at a high productivity and with a high precision based using patterns formed at a high productivity and with a high precision.

In such a manner, according to the third embodiment, semiconductor devices having a high performance and a high reliability can be produced with a high efficiency and at a low cost, while easily improving the yield, quality and reliability of the semiconductor devices. Also, the semiconductor device according to the third embodiment has a high quality, a high reliability and a high performance, and is also manufactured at a low cost.

Furthermore, the pattern forming method, the semiconductor device and the method for manufacturing the same, according to the present invention, are not limited to those according to the first to third embodiments. Part of their structures or steps can be variously modified, or the structures or steps can be appropriately combined as required in order that they be put to practical use, without departing from the spirit or scope of the general inventive concept as defined by the appended claims and their equivalents.

For example, the pH value of the water-soluble anti-charge film 5 is not necessarily required to be adjusted to 5. It may be set at, e.g., 7, i.e., it may be set to be neutral.

The thickness of the water-soluble anti-charge film 5 is not limited to approximately 10 nm, which is the value set in the first embodiment, or approximately 5 nm, which is the value set in the second embodiment. It has been discovered from the result of an experiment conducted by the inventors of the present invention that when the thickness of the water-soluble anti-charge film 5 is set at approximately 50 nm or less, the same advantages can be obtained as in the first and second embodiments.

The position of the organic anti-reflection film 6 is not limited to that set in the first embodiment or the second embodiment. The organic anti-reflection film 6 may be provided between the water-soluble anti-charge film 5 and the resist film 7.

Furthermore, in the second embodiment, the acceleration voltage at which an electron beam is applied in order to write a pattern is set at approximately 5 keV, however, it is not limited to that value. From the result of an experiment made by the inventors of the present invention, it has been discovered that the same advantages can be obtained as in the first and second embodiments, when the above acceleration voltage is approximately 10 keV. That is, it has been found that under the above condition, the electron beam barely damages the water-soluble anti-charge film 5, the organic lower film 11 and the silicon oxide film 4, etc., and in addition, pattern formation can be easily carried out with a high precision.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A pattern forming method comprising:
providing a first film having conductivity above a substrate to be processed;
providing a second film having an acid diffusion preventing function above the first film;
providing a third film having photosensitivity on the second film; and
exposing a predetermined pattern on the third film by applying an energy beam onto the third film.

2. The pattern forming method according to claim 1, wherein a film containing a component which is cross-linked when being heated is used as the first film, and is heated.

3. The pattern forming method according to claim 1, further comprising applying an addition agent to the first film, whereby the first film is weakly acid or neutral.

4. The pattern forming method according to claim 1, wherein the first film is formed to have a thickness of 50 nm or less.

5. The pattern forming method according to claim 1, wherein the first film is heated at 100° C. or more.

6. The pattern forming method according to claim 1, wherein a film containing a component which is cross-linked when being heated is used as the second film, and is heated.

7. The pattern forming method according to claim 1, wherein a film becomes more minute when being heated is used as the second film.

8. The pattern forming method according to claim 1, wherein the second film is heated at 200° C.

9. The pattern forming method according to claim 1, wherein a chemical amplified type of resist film is used as the third film.

10. The pattern forming method according to claim 1, further comprising providing a fourth film between the substrate and the first film, the fourth film is used for transferring the pattern exposed on the third film onto the substrate.

11. The pattern forming method according to claim 2, wherein a water-soluble organic film is used as the first film, the water-soluble organic film containing a component which is cross-linked and insolubilized for at least one of water or an alkali solution, when being heated.

12. The pattern forming method according to claim 2, wherein a water-soluble anti-charge film is used as the first film, the water-soluble anti-charge film containing a component which is cross-linked and insolubilized for at least one of water or an alkali solution, when being heated.

13. The pattern forming method according to claim 5, wherein the first film is heated a plurality of times at different temperatures of 100° C. or more.

14. The pattern forming method according to claim 6, wherein an organic film is used as the second film, the organic film containing a thermal cross-linker which causes cross-linking when being heated.

15. The pattern forming method according to claim 10, wherein an organic film is used as the fourth film, the organic film being non-photosensitive, and containing carbon as a main component.

16. The pattern forming method according to claim 10, wherein the energy beam is applied at an acceleration voltage of 10 keV or less.

17. The pattern forming method according to claim 10, further comprising:
providing a fifth film between the first film and the second film;
processing the second film, the fifth film and the first film by using the pattern exposed on the third film as a mask;
processing the fourth film by using the processed second film, fifth film and first film and the pattern exposed on the third film as a mask; and
forming the pattern in an outer layer portion of the substrate by using the processed fourth film as a mask.

18. The pattern forming method according to claim 12, wherein the water-soluble anti-charge film contains a PTAS which is cross-linked when being heated.

19. A method for manufacturing a semiconductor device comprising:
providing a first film having conductivity above a semiconductor substrate;
providing a second film having an acid diffusion preventing function above the first film;
providing a third film having photosensitivity on the second film;
exposing a predetermined pattern on the third film by applying an energy beam onto the third film; and
forming the pattern in the semiconductor substrate.

20. A semiconductor device comprising:
a semiconductor substrate where a predetermined pattern is formed,
wherein:
the pattern is exposed on a third film having photosensitivity, which is provided above the semiconductor substrate, by applying an energy beam onto the third film;
the third film is provided on a second film which has an acid diffusion preventing function, and which is provided above the semiconductor substrate; and
the second film is provided above a first film which has conductivity, and which is provided above the semiconductor substrate.
